(19) United States
(12) Patent Application Publication
(10) Pub. No.: US 2025/0185434 A1
(43) Pub. Date: Jun. 5, 2025

(54) LIGHT-EMITTING MODULE AND SMARTPHONE

(71) Applicant: NICHIA CORPORATION, Anan-shi (JP)

(72) Inventor: Shinya MATSUOKA, Anan-shi (JP)

(73) Assignee: NICHIA CORPORATION, Anan-shi (JP)

(21) Appl. No.: 18/960,254

(22) Filed: Nov. 26, 2024

(30) Foreign Application Priority Data
Nov. 30, 2023 (JP) 2023-203356

(51) Int. Cl. H10H 29/24; F21V 14/02; G06V 40/13; H10H 29/14; H10H 29/851; H10H 29/855

(52) U.S. Cl. CPC H10H 29/24; F21V 14/02; G06V 40/1318; H10H 29/142; H10H 29/8513; H10H 29/855

(57) ABSTRACT

A light-emitting module includes: a substrate; plurality of light sources disposed on the substrate, the plurality of light sources including a red light source, a green light source, a blue light source, and an infrared light source; at least one light-receiving element disposed on the substrate; and a lens disposed facing the plurality of light sources and the at least one light-receiving element. The red light source includes: a first light-emitting element configured to emit blue light, and a first phosphor configured to convert a wavelength of at least part of the blue light emitted from the first light-emitting element to emit red light. The at least one light-receiving element is configured to output biological photodetection information obtained by receiving light that has been emitted from at least one of the plurality of light sources and reflected or scattered by a biological body.

### CROSS-REFERENCE TO RELATED APPLICATION

This application claims priority to Japanese Patent Application No. 2023-203356, filed on Nov. 30, 2023, the disclosure of which is hereby incorporated by reference in its entirety.

### TECHNICAL FIELD

The present disclosure relates to a light-emitting module and a smartphone.

### BACKGROUND

For example, Japanese Patent Publication No. 2019-533178 discloses a light-emitting module that emits light from a flash lamp.

### SUMMARY

An object of an embodiment according to the present disclosure is to provide a light-emitting module that can emit white light and can output biological photodetection information used for obtaining biological information.

A light-emitting module according to an embodiment of the present disclosure includes a substrate, at least one light source disposed on the substrate, at least one light-receiving element disposed on the substrate, and a lens disposed facing the light source and the light-receiving element. The at least one light source can emit white light composed of mixed-color light of red light, green light, and blue light, and the at least one light-receiving element outputs biological photodetection information obtained by receiving at least one of reflected light and scattered light by a biological body of light emitted from the at least one light source.

According to an embodiment of the present disclosure, it is possible to provide a light-emitting module that can emit white light and can output biological photodetection information used for obtaining biological information.

### BRIEF DESCRIPTION OF DRAWINGS

FIG. 1 is a schematic top view of a light-emitting module according to a first embodiment.

FIG. 2 is a schematic cross-sectional view taken along line II-II in FIG. 1.

FIG. 3 is a diagram showing an example of emission spectra of a red light source, a green light source, and a blue light source of the light-emitting module according to the first embodiment.

FIG. 4 is a diagram showing an example of reflection spectra of metals.

FIG. 5 is a diagram showing an example of an emission spectrum of a white light source of the light-emitting module according to the first embodiment.

FIG. 6 is a schematic cross-sectional view illustrating an emitting operation of white light by the light-emitting module according to the first embodiment.

FIG. 7 is a schematic cross-sectional view of the light-emitting module illustrating an emitting operation of light when biological photodetection information is output by the light-emitting module according to the first embodiment.

FIG. 8A is a schematic cross-sectional view illustrating a configuration of a red light source including a first phosphor of a light-emitting module according to a first modified example.

FIG. 8B is a schematic cross-sectional view illustrating a configuration of a green light source including a second phosphor of the light-emitting module according to the first modified example.

FIG. 9 is a diagram showing an example of an emission spectrum of the red light source including the first phosphor.

FIG. 10 is a diagram showing an example of an emission spectrum of the green light source including the second phosphor.

FIG. 11 is a schematic top view illustrating a substrate on which a light source is disposed in a light-emitting module according to a second modified example.

FIG. 12 is a schematic top view illustrating a substrate on which a light source is disposed in a light-emitting module according to a third modified example.

FIG. 13 is a schematic top view of a light-emitting module according to a second embodiment.

FIG. 14 is a schematic cross-sectional view taken along line XIV-XIV in FIG. 13.

FIG. 15 is a schematic cross-sectional view illustrating a configuration of an infrared light source including a third phosphor of the light-emitting module according to the second embodiment.

FIG. 16 is a schematic view of a smartphone according to a third embodiment viewed from the side opposite to a display surface side.

FIG. 17 is a schematic view of the smartphone according to the third embodiment viewed from the display surface side.

FIG. 18 is a schematic cross-sectional view taken along line XVIII-XVIII illustrated in FIG. 16.

### DETAILED DESCRIPTION

A light-emitting module and a smartphone according to embodiments of the present disclosure will be described in detail with reference to the drawings. The following embodiments exemplify the light-emitting module and the smartphone for embodying the technical concept of the present disclosure, but limitation to the following embodiments is not intended. Further, dimensions, materials, shapes, relative arrangements, or the like of constituent members described in the embodiments are not intended to limit the scope of the present disclosure thereto, unless otherwise specified, and are merely exemplary. Note that the sizes, positional relationship, or the like of members illustrated in each of the drawings may be exaggerated for clarity of description. Further, in the following description, members having the same terms and reference characters represent the same or similar members, and a detailed description of these members will be omitted as appropriate. As a cross-sectional view, an end view illustrating only a cut surface may be used.

For clarity of explanation, the arrangement and structures of portions will be described using the XYZ orthogonal coordinate system in the following description. The X, Y, and Z-axes are orthogonal to each other. The direction in which the X-axis extends is referred to as the “X-direction,” the direction in which the Y-axis extends as the “Y-direction,” and the direction in which the Z-axis extends as the “Z-direction.”

In addition, in the X-direction, a direction in which an arrow is directed is referred to as a “+X-direction” or “+X side,” and a direction opposite to the +X-direction is referred to as a “−X-direction” or “−X side.” In the Y-direction, a direction in which an arrow is directed is referred to as a “+Y-direction” or a “+Y side” and a direction opposite to the +Y-direction is referred to as a “−Y-direction” or a “−Y side.” In the Z-direction, a direction in which the arrow is directed is referred to as a “+Z-direction,” a “+Z side,” an “upper side,” or “upward,” and a direction opposite to the +Z-direction is referred to as a “−Z-direction,” a “−Z side,” a “lower side,” or “downward.” However, these are used merely to describe a relative relationship of positions, orientations, directions, and the like, and the expressions do not have to match a relationship at a time of use. Also, these directions have no relation to the direction of gravity.

In the embodiments, the light source included in the light-emitting module emits light in the +Z-direction as an example. A surface of a target object when viewed from the +Z-direction is referred to as an “upper surface,” and a surface of the target object when viewed from the −Z-direction is referred to as a “lower surface.” In the following embodiments, “being aligned with the X-axis, the Y-axis, or the Z-axis” includes the case in which an object has an inclination within a range of ±10° relative to the corresponding axis. In the present embodiments, the orthogonality may include a tolerance within ±10° with respect to 90°.

In the present specification or the claims, when there are a plurality of components and it is desired to denote those components individually, the components may be distinguished by adding terms such as “first,” “second,” and the like in front of terms of the components. Objects to be distinguished may differ between the present specification and the claims.

### First Embodiment

### Configuration of Light-Emitting Module According to First Embodiment

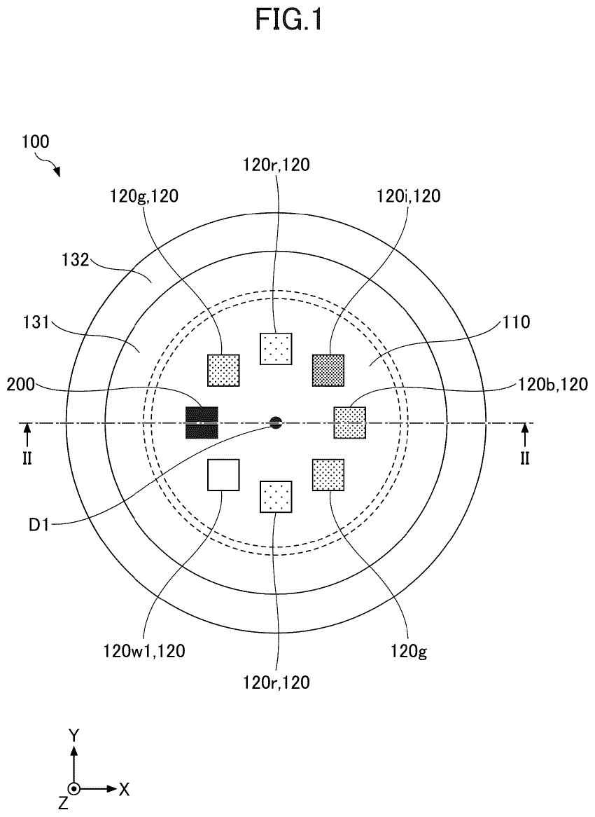

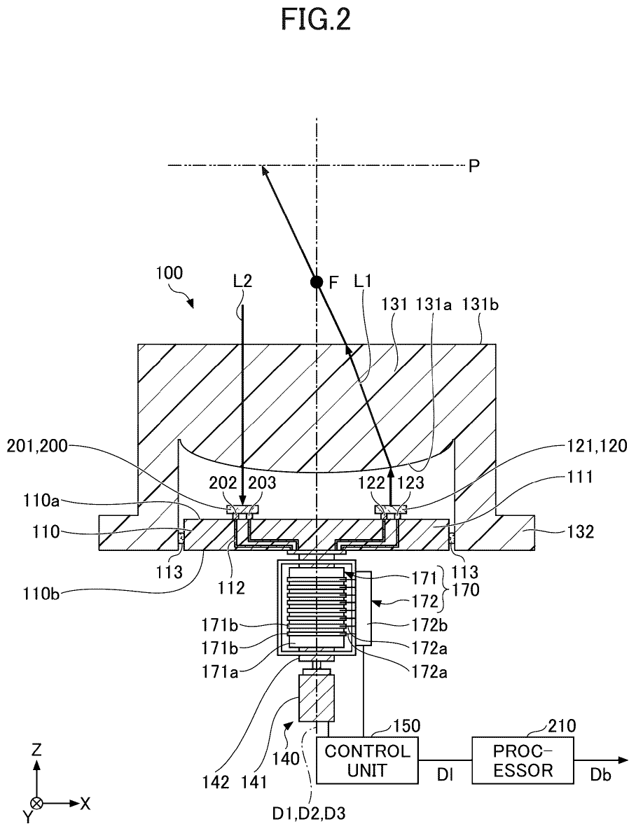

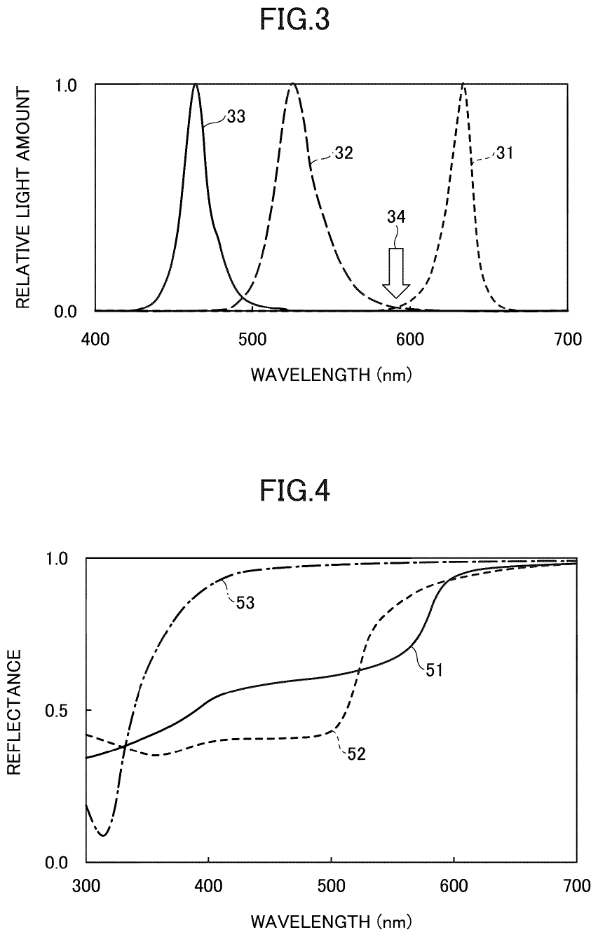

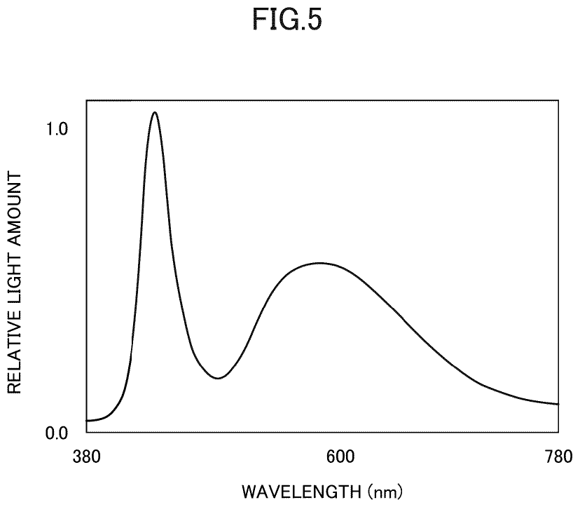

A light-emitting module according to a first embodiment is described with reference to FIGS. 1 to 5. FIG. 1 is a schematic top view illustrating an example of a light-emitting module 100 according to a first embodiment. FIG. 2 is a schematic cross-sectional view taken along line II-II in FIG. 1. FIG. 3 is a diagram showing an example of emission spectra of a red light source 120r, a green light source 120g, and a blue light source 120b of the light-emitting module 100. FIG. 4 is a diagram showing an example of reflection spectra of metals. FIG. 5 is a diagram showing an example of an emission spectrum of a white light source 120w1 of the light-emitting module 100.

In FIG. 2, part of light emitted from a light source 120 included in the light-emitting module 100 is indicated by an arrow as emitted light L1, and part of light incident on the light-emitting module 100 from the outside of the light-emitting module 100 is indicated by an arrow as incident light L2. In addition, in FIG. 2, for the purpose of indicating that a central axis D1 of a substrate 110, a rotation axis D2 of the substrate 110, and an optical axis D3 of a lens 131 substantially coincide with each other, the reference characters of the central axis D1, the rotation axis D2, and the optical axis D3 are added. Also in the following description, reference characters may be added for the same purpose. For the sake of brevity, the arrow L2 in FIG. 2 is illustrated while omitting a change in a traveling direction due to differences in refractive index between the members.

As illustrated in FIGS. 1 and 2, the light-emitting module 100 includes the substrate 110, at least one light source 120 disposed on the substrate 110, at least one light-receiving element 200 disposed on the substrate 110, and a lens 131 disposed facing the light source 120 and the light-receiving element 200. The at least one light source 120 can emit white light composed of mixed-color light of red light, green light, and blue light. The at least one light-receiving element 200 outputs biological photodetection information DL obtained by receiving at least one of reflected light and scattered light by a biological body of light emitted from the at least one light source 120.

In the present embodiment, the at least one light source 120 includes a plurality of the light sources 120. The plurality of light sources 120 include at least one red light source 120r that emits red light, at least one green light source 120g that emits green light, at least one blue light source 120b that emits blue light, and at least one infrared light source 120i that emits infrared light. In the example illustrated in FIG. 1, the plurality of light sources 120 include at least one white light source 120w1 that emits the white light. The at least one light-receiving element 200 outputs biological photodetection information DL obtained by receiving at least one of the reflected light and the scattered light by the biological body of light emitted from the plurality of light sources 120.

In the example illustrated in FIG. 1, for the purpose of indicating that the plurality of light sources 120 include the red light source 120r, the green light sources 120g, the blue light sources 120b, the infrared light source 120i, and the white light source 120w1, the reference character of the light source 120 is added to the reference character of each of the red light source 120r, the green light source 120g, the blue light source 120b, the infrared light source 120i, and the white light source 120w1. Also in the following description, reference characters may be added for the same purpose. In the example illustrated in FIG. 2, the biological photodetection information DL represents information output from the light-receiving element 200 and output via a control unit 150 and the like.

The light-emitting module 100 may irradiate an irradiation surface P with the white light emitted from the at least one light source 120. The irradiation surface P illustrated in FIG. 1 is a virtual surface. A processor 210 that receives the biological photodetection information DL output from the light-emitting module 100 can obtain biological information Db related to the biological body based on the biological photodetection information DL. As described above, in the present embodiment, it is possible to provide the light-emitting module 100 that can emit the white light and can output the biological photodetection information DL used for obtaining the biological information Db. The light-emitting module 100 may include a memory separately from the processor 210, and the processor 210 may obtain the biological information Db with reference to information stored or temporarily stored in the memory. The light-emitting module 100 may output the biological photodetection information DL to an external device such as a personal computer (PC), a smartphone, or a smart watch, and the external device may obtain the biological information Db based on the biological photodetection information DL.

The biological photodetection information DL is, for example, analog voltage information output from the light-receiving element 200. The biological photodetection information DL includes at least analog current information obtained from at least one of reflected light and scattered light of green light by the biological body, analog current information obtained from at least one of reflected light and scattered light of red light or infrared light by the biological body, and the like. The analog current information (that is, the biological photodetection information DL) received by the light-receiving element 200 is converted, via the processor 210, into the biological information Db related to a pulse or a blood oxygen concentration.

The light-emitting module 100 can individually emit light from the light source that can appropriately emit light of a necessary wavelength at the time of vital check by individually driving the red light source 120r, the green light source 120g, the blue light source 120b, and the infrared light source 120i as the plurality of light sources 120. Accordingly, even when the light-emitting module 100 includes only one light-receiving element 200, the light-emitting module 100 can recognize the color of the light from the biological body received by the light-receiving element 200 by associating the color of the light from the biological body with the light source emitting the light among the plurality of light sources 120.

By driving the red light source 120r, the green light source 120g, and the blue light source 120b at the same time, the light-emitting module 100 can emit the white light composed of the mixed-color light of red light, green light, and blue light. In the present embodiment, the white light obtained from the mixed-color light of red, green, and blue has three peaks as peak wavelengths in the wavelength regions of red, green, and blue in the emission spectrum. In this case, in the mixed-color light of red light, green light, and blue light, a wavelength region with a small light amount is likely to occur in a wavelength region between the peaks. In particular, the wavelength region with the small light amount is likely to occur in an orange wavelength region between red and green wavelength regions, for example. Thus, when this white light is used as a flash light source for a camera or the like, reflected light that accurately reflects the color of an object may not be obtained. For example, in the example illustrated in FIG. 3, a red light relative light amount distribution 31, a green light relative light amount distribution 32, a blue light relative light amount distribution 33, and a boundary wavelength region 34 are shown. The relative light amount distribution shown in FIG. 3 means a relative light amount distribution for each wavelength. The boundary wavelength region 34 is a wavelength region near 600 nm between the red light relative light amount distribution 31 and the green light relative light amount distribution 32, and represents a wavelength region with a small light amount.

On the other hand, in the example shown in FIG. 4, the solid line graph represents the reflectance distribution of copper 51, the dashed line graph represents the reflectance distribution of silver 52, and the dot-dash line graph represents the reflectance distribution of gold 53. The reflectance distribution in FIG. 4 means a reflectance distribution for each wavelength. For example, in the reflectance distribution 51 of copper, the reflectance is higher in a wavelength region of 600 nm or more than in a wavelength region of lower than 600 nm. Thus, when the light amount in the wavelength region near 600 nm of light emitted to the copper is small, the reflected light that accurately reflects the color of copper may not be obtained. Thus, when white light having the wavelength region with a small light amount is used as an application for a flash of a camera, the reflected light accurately reflecting the color of an object cannot be obtained, and a shot image cannot accurately express the color of the object, in some cases.

On the other hand, the light-emitting module 100 includes the white light source 120w1 in the plurality of light sources 120. The white light source 120w1 includes, for example, a light-emitting element that emits blue light and a phosphor that is excited by the blue light to emit yellow light. Thus, as shown in FIG. 5, the white light source 120w1 contains a large light amount in the boundary wavelength region 34 near 600 nm. Specifically, the emission spectrum of the white light source 120w1 preferably has a light intensity of ⅓ or more of the peak intensity of the emission spectrum of the blue light at the boundary wavelength region 34 near 600 nm, more preferably has ½ of the light intensity of the emission spectrum of the blue light. Thus, in the light-emitting module 100, the light amount in the boundary wavelength region 34, which is insufficient only with the light emitted from the red light source 120r, the green light source 120g, and the blue light source 120b, can be compensated for by the emitted light from the white light source 120w1. Accordingly, for example, an imaging device that performs photographing using irradiation light from the light-emitting module 100 can obtain the reflected light accurately reflecting the color of an object, and can perform photographing accurately representing the color of the object.

The plurality of light sources 120 include the white light source 120w1, the red light source 120r, the green light source 120g, and the blue light source 120b, and thus the light-emitting module 100 can adjust the color temperature of the white light emitted from the light-emitting module. Accordingly, the imaging device that performs photographing using the irradiation light from the light-emitting module 100 can emit white light having a desired color temperature.

In the example illustrated in FIG. 2, the light-emitting module 100 includes the processor 210 that can output the biological information Db based on the biological photodetection information DL output from the light-receiving element 200. The processor 210 includes a central processing unit (CPU), a digital signal processor (DSP), or the like.

In the example illustrated in FIG. 2, the processor 210 obtains the biological information Db by calculation based on the biological photodetection information DL received from the light-receiving element 200 via the control unit 150. The light-emitting module 100 includes the processor 210, and thus the light-emitting module 100 can output the biological information Db to the external device. The biological information Db is, for example, pulse information, blood oxygen concentration information, or the like. The biological information Db is calculated using a digital signal obtained by analog-to-digital conversion of the biological photodetection information DL as an analog voltage signal. Examples of the external device include a PC, a smartphone, a smartwatch, a tablet terminal, a display device such as a liquid crystal display, a storage device such as a hard disk drive (HDD), and a communication device connected to a network.

In the light-emitting module 100, the plurality of light sources 120 may be arranged in a linear shape or in a matrix shape, or may be arranged in a circular ring shape. In particular, in the light-emitting module 100, the plurality of light sources are preferably arranged in the circular ring shape. In the example illustrated in FIG. 1, two red light sources 120r, two green light sources 120g, one blue light source 120b, one white light source 120w1, and one infrared light source 120i are arranged in the circular ring shape on the upper surface of the substrate 110. The plurality of light sources 120 are arranged in the circular ring shape, and thus light can be emitted in a direction symmetrical with respect to the center of the circular ring shape. Accordingly, a directional dependence of light reception sensitivity of at least one of the reflected light and the scattered light by the biological body can be reduced. For example, when the plurality of light sources 120 are arranged biased in one direction by being linearly arranged or the like, the directional dependence may occur in the light reception sensitivity of at least one of the reflected light and the scattered light by the biological body. The directional dependence of the sensitivity means a difference in the light reception sensitivity depending on a direction; for example, a light reception sensitivity of light from any other direction is lower than a light reception sensitivity of light from a predetermined direction. In the present embodiment, the plurality of light sources are arranged in the circular ring shape, and thus the directional dependence of the light reception sensitivity can be suppressed. Further, in the light-emitting module 100, acquisition accuracy of the biological information Db based on the biological photodetection information DL can be increased.

In addition, for example, when there is an inhibitory element such as a tattoo that absorbs light emitted from the plurality of light sources 120 in a part of the biological body from which the biological photodetection information DL is obtained, the irradiation light may be absorbed by the inhibitory element at a position to which the light is emitted. When the irradiation light is absorbed, the light amount received by the light-receiving element 200 decreases, and thus the acquisition accuracy of the biological information Db based on the biological photodetection information DL may decrease. On the other hand, as illustrated in FIGS. 1 and 2, the light-emitting module 100 includes a driving unit 140 that can rotate the substrate 110 about the central axis D1 of the circular ring shape as the rotation axis D2. The central axis D1 is an axis that is substantially parallel to a normal line (for example, a line extending in the Z-direction) of the substrate 110 and passes through the center of the circular ring shape in a top view. The light-emitting module 100 can rotate, around the rotation axis D2, the plurality of light sources 120 arranged in the circular ring shape when the driving unit 140 rotates the substrate 110. A position of irradiation from the light-emitting module 100 moves on the biological body by the rotation of the plurality of light sources 120, and thus the light-receiving element 200 of the light-emitting module 100 can receive at least one of the reflected light and the scattered light from a portion in which there is no inhibitory element such as a tattoo. As a result, in the present embodiment, as compared with a case in which the plurality of light sources 120 do not move, the influence of the inhibitory element such as a tattoo can be reduced, and the acquisition accuracy of the biological information Db based on the biological photodetection information DL can be increased.

In the example illustrated in FIG. 2, the rotation axis D2 of the substrate 110 driven by the driving unit 140 coincides with the optical axis D3 of the lens 131. Accordingly, in the light-emitting module 100, light distribution control of the light emitted from the plurality of light sources 120 by the lens 131 can be facilitated as compared with at least one of a case in which the rotation axis D2 of the substrate 110 is tilted with respect to the optical axis D3 of the lens 131 and a case in which the rotation axis D2 of the substrate 110 is shifted.

In the example illustrated in FIG. 2, the light-emitting module 100 includes the control unit 150 that can control emission of light from the plurality of light sources 120. The control unit 150 includes, for example, a CPU and a memory. In the light-emitting module 100, the control unit 150 can switch between emission of the white light and emission of the light when outputting the biological photodetection information DL. In the light-emitting module 100, the control unit 150 controls the light amount for each color according to the characteristics of the biological body from which the biological information Db is obtained, and thus the acquisition accuracy of the biological information Db can be increased.

A configuration of the light-emitting module 100 will be described in detail below.

### Substrate 110

In the example illustrated in FIG. 2, the substrate 110 is a wiring substrate including a resin layer 111 and a plurality of wirings 112. The surface of the substrate 110 includes an upper surface 110a and a lower surface 110b located opposite to the upper surface 110a. The upper surface 110a and the lower surface 110b are substantially flat and are substantially parallel to the XY plane. The plurality of wirings 112 are provided at least on the upper surface 110a of the substrate 110. The wirings 112 may be further provided on the lower surface 110b and/or in the substrate 110. In the example illustrated in FIG. 1, a shape of an outer edge of the substrate 110 in a top view is a substantially circular shape. However, the shape of the outer edge of the substrate 110 in the top view is not limited to the above, and may be a substantially rectangular shape, a substantially elliptical shape, a substantially polygonal shape, or the like.

### Light Source 120

In the example illustrated in FIG. 1, the plurality of light sources 120 are disposed on the substrate 110, in other words, on the upper surface 110a of the substrate 110. The plurality of light source 120 includes a light-emitting element 121, which is a semiconductor layered body, and at least a pair of electrodes 122 and 123 disposed on a lower surface of the light-emitting element 121. The red light source 120r includes a light-emitting element 121 that emits red light. The green light source 120g includes a light-emitting element 121 that emits green light. The blue light source 120b includes a light-emitting element 121 that emits blue light. The infrared light source 120i includes a light-emitting element 121 that emits infrared light. The red light source 120r, the green light source 120g, and the infrared light source 120i may be light sources each including a light-emitting element that emits blue light and a phosphor that emits a corresponding one of red light, green light, and infrared light as a wavelength conversion member disposed on the light-emitting element.

The light-emitting element 121 is, for example, a light-emitting diode (LED). In the light-emitting element 121, a substrate having transmissivity, a substrate having transmissivity and light diffusivity, or the like may be further disposed on the semiconductor layered body. The transmissivity of the substrate disposed on the semiconductor layered body is preferably a transmittance of 60% or more with respect to the light emitted from the light-emitting element 121.

The light-emitting element 121 includes an n-type semiconductor layer, an active layer, and a p-type semiconductor layer. The shape of the outer edge of the light-emitting element 121 in a bottom view is a quadrangular shape in which two opposing sides of four sides are substantially parallel to the X-direction and the remaining two opposing sides of the four sides are substantially parallel to the Y-direction. The light-emitting element 121, in other words, the light source 120 has a quadrangular shape with a side in a range from 50 μm to 1000 μm on the upper surface, for example. However, the shape of the outer edge of the light-emitting element 121 in a bottom view is not limited thereto.

One of the pair of electrodes 122 and 123 is electrically connected to the n-type semiconductor layer of the light-emitting element 121, and the other is electrically connected to the p-type semiconductor layer of the light-emitting element 121. The electrode 122 and the electrode 123 of each of the plurality of light sources 120 are electrically connected to corresponding ones of the plurality of wirings 112 of the substrate 110. Thus, the output of each light source 120 can be individually controlled.

A shape of each of the pair of electrodes 122 and 123 and a direction in which the pair of electrodes 122 and 123 are arranged can be selected as appropriate. For example, the pair of electrodes 122 and 123 may have shapes different from each other so that an electrode electrically connected to the p-type semiconductor layer and an electrode electrically connected to the n-type semiconductor layer can be easily distinguished from each other. The pair of electrodes 122 and 123 may be arranged in the X-direction or the Y-direction, and the shape of each of the pair of electrodes 122 and 123 may be a substantially rectangular shape, a substantially circular shape, a substantially elliptical shape, a substantially polygonal shape, or the like.

### Light-Receiving Element 200

In the example illustrated in FIG. 1, the light-receiving element 200 is disposed on the substrate 110, in other words, on the upper surface 110a of the substrate 110. In the example illustrated in FIG. 1, the light-receiving element 200 is disposed in a part of the circular ring shape formed by the plurality of light sources 120 disposed on the upper surface 110a of the substrate 110. In the example illustrated in FIG. 2, the light-receiving element 200 includes a photoelectric conversion unit 201, which is a semiconductor layered body, and at least a pair of electrodes 202 and 203 disposed on a lower surface of the photoelectric conversion unit 201.

The light-receiving element 200 is, for example, a photo diode (PD). The light-receiving element 200 can convert light energy of the received light into electrical energy, and output a signal related to a current value according to the light energy as the biological photodetection information DL. In the light-receiving element 200, a substrate having transmissivity, an anti-reflective film, or the like may be further disposed on the semiconductor layered body. The transmissivity of the substrate disposed on the semiconductor layered body is preferably a transmittance of 60% or more with respect to the light emitted from the light-emitting element 121.

The photoelectric conversion unit 201 includes a pn junction of the n-type semiconductor layer and the p-type semiconductor layer. The shape of the outer edge of the photoelectric conversion unit 201 in a bottom view is a quadrangular shape in which two opposing sides of four sides are substantially parallel to the X-direction and the remaining two opposing sides of the four sides are substantially parallel to the Y-direction. However, the shape of the outer edge of the photoelectric conversion unit 201 in a bottom view is not limited thereto.

One of the pair of electrodes 202 and 203 is electrically connected to the n-type semiconductor layer of the photoelectric conversion unit 201, and the other is electrically connected to the p-type semiconductor layer of the photoelectric conversion unit 201. The electrodes 202 and 203 of the photoelectric conversion unit 201 are electrically connected in pairs to corresponding ones of the plurality of wirings 112 of the substrate 110.

A shape of each of the pair of electrodes 202 and 203 and a direction in which the pair of electrodes 202 and 203 are arranged can be selected as appropriate. For example, the pair of electrodes 202 and 203 may have shapes different from each other so that an electrode electrically connected to the p-type semiconductor layer and an electrode electrically connected to the n-type semiconductor layer can be easily distinguished from each other. The pair of electrodes 202 and 203 may be arranged in the X-direction or the Y-direction, and the shape of each of the pair of electrodes 202 and 203 may be a substantially rectangular shape, a substantially circular shape, a substantially elliptical shape, a substantially polygonal shape, or the like. At least one of the pair of electrodes 202 and 203 may be provided on the upper surface of the light-receiving element 200. In this case, at least one of the electrodes 202 and 203 provided on the upper surface of the light-receiving element 200 is electrically connected to a corresponding one of the plurality of wirings 112 of the substrate 110 via a conductive member such as a wire.

An area of a light-receiving surface of the light-receiving element 200 is preferably larger than an area of a light-emitting surface of the light source 120. The area of the light-receiving surface of the light-receiving element 200 is made larger than the area of the light-emitting surface of the light source 120, and thus the light reception sensitivity of the light-receiving element 200 can be increased as compared with a case in which the area of the light-receiving surface of the light-receiving element 200 is equal to or smaller than the area of the light-emitting surface of the light source 120. Accordingly, because the light amount of the emitted light from the light source 120 can be reduced when the biological information Db is obtained, damage to a skin of the biological body irradiated with the emitted light can be reduced, and the likelihood of roughness of the skin of the biological body can be reduced, for example.

### Lens 131

The light emitted from the plurality of light sources 120 is incident on the lens 131. The lens 131 is disposed above the plurality of light sources 120 at a distance apart from the plurality of light sources 120. The shortest distance between the lens 131 and the plurality of light sources 120 is, for example, in a range from 50 μm to 1000 μm. The lens 131 is a rotationally symmetric body with the rotation axis D2 of the substrate 110 as the central axis. Here, the rotationally symmetric body means a three-dimensional object having rotational symmetry. The rotation axis D2 of the substrate 110 substantially coincides with the optical axis D3 of the lens 131.

In the example illustrated in FIG. 2, the lens 131 is a lens having a convex surface protruding toward the plurality of light sources 120 side. The lens 131 includes a light incident surface 131a facing the plurality of light sources 120 and a light-exiting surface 131b located on the opposite side of the light incident surface 131a. The light incident surface 131a is the convex surface protruding toward the plurality of light sources 120 side. The light-exiting surface 131b is flat and substantially parallel to the XY plane. The lens 131 is bonded with an adhesive member 113 disposed between an inner surface of the lens 131 and the substrate 110. The lens 131 and the substrate 110 do not have to be bonded to each other, and for example, only the substrate 110 may be rotated.

In the example illustrated in FIG. 1, in a top view, the plurality of light sources 120 and the light-receiving element 200 are disposed such that the distance between each of the centers thereof and the central axis D1 of the substrate 110 is substantially equal. In the example illustrated in FIG. 2, the emitted light L1, which is part of the light emitted from the light source 120, passes through the lens 131, passes through a focal point F, and then propagates further away from the rotation axis D2 as advancing toward the +Z-direction. The incident light L2 on the lens 131 from the outside of the light-emitting module 100 is transmitted through the lens 131 and then incident on the light-receiving element 200.

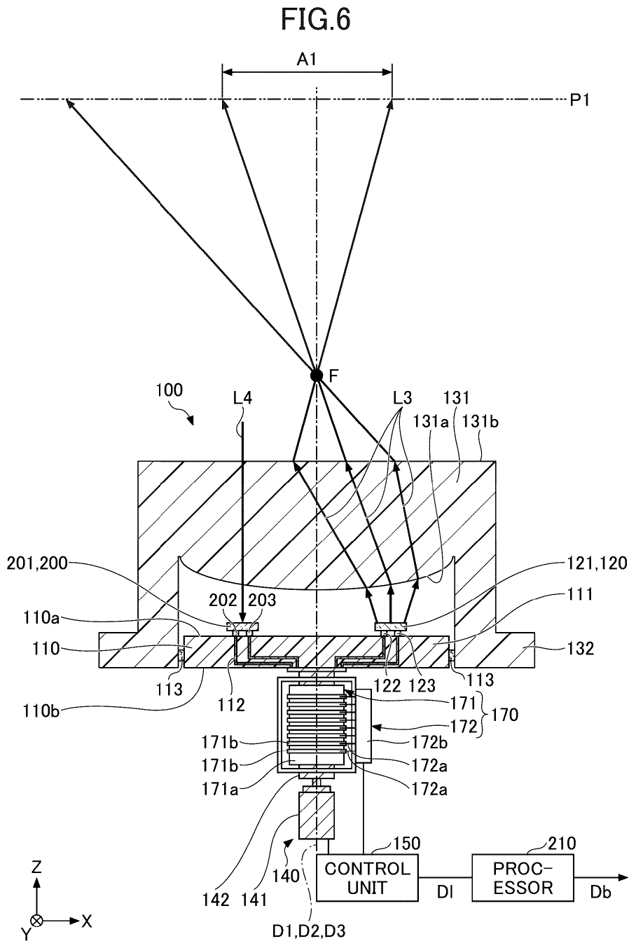

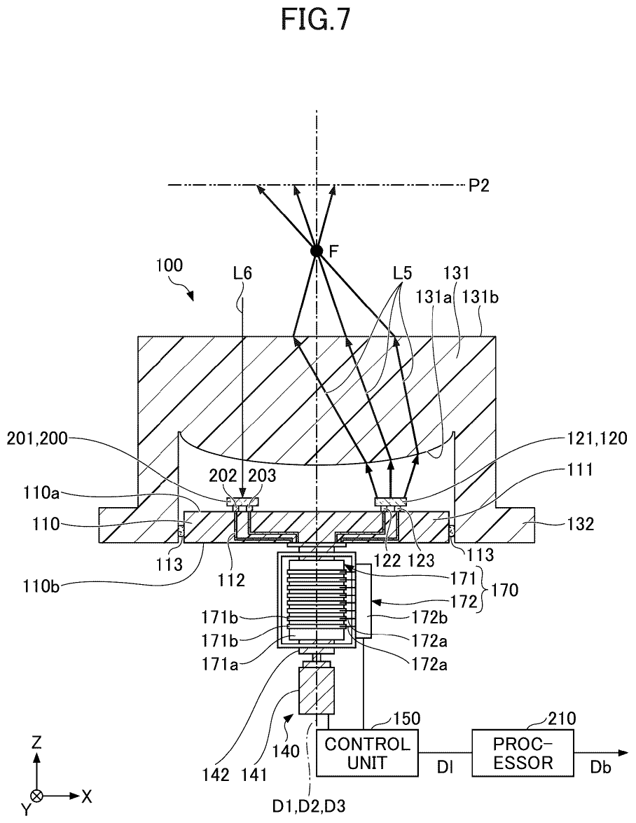

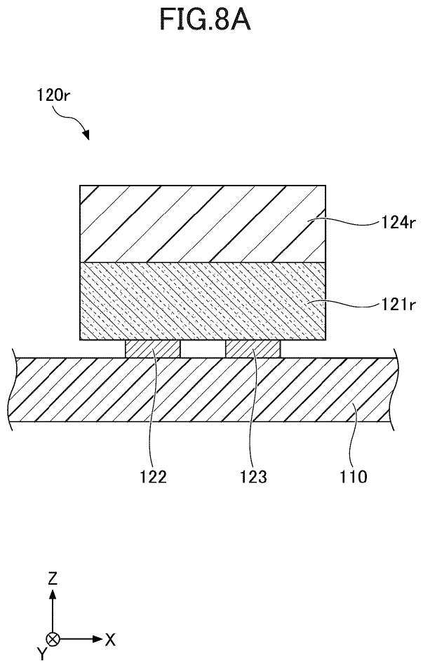

For ease of illustration, in FIG. 2, part of light emitted from one of the plurality of light sources 120 is illustrated as the emitted light L1. However, although the direction of the emitted light from each of the plurality of light sources 120 differs according to the position where each of the plurality of light sources 120 is disposed, the emitted light behaves in the same or similar manner as the emitted light L1 illustrated in FIG. 2 in that part of the emitted light passes through the lens 131, passes through the focal point F, and then propagates further away from the rotation axis D2 as advancing toward the +Z-direction. Thus, the emitted light L1 illustrated in FIG. 2 may be regarded as the emitted light from each of the plurality of light sources 120. This also applies to FIGS. 6 and 7.

In the example illustrated in FIG. 2, a support portion 132 extending downward from an outer peripheral portion of the lens 131 is provided on an outer peripheral portion of the lens 131. The support portion 132 is formed integrally with the lens 131. The support portion 132 has a tubular shape surrounding the plurality of light sources 120 in a top view. However, the shape of the support portion 132 is not limited to the tubular shape. For example, a plurality of support portions each having a columnar shape may be disposed on an outer periphery of the lens 131. The support portion 132 may be made of a material different from a material of the lens 131. In this case, the support portion 132 does not have to have transmissivity.

### Driving Unit 140 and Control Unit 150

The control unit 150 can control emission of the light from the plurality of light sources 120 and can output the biological photodetection information DL output from the light-receiving element 200 to the processor 210. Further, the control unit 150 of the light-emitting module 100 can control the rotation of the substrate via the driving unit 140. In the example illustrated in FIG. 2, the driving unit 140 includes a motor 141 and a shaft 142 that is connected to the substrate 110 and in conjunction with the motor 141. When the motor 141 is driven, the shaft 142 rotates. With the rotation of the shaft 142, the substrate 110 rotates around the rotation axis D2. As described above, in the light-emitting module 100, the rotation axis D2 substantially coincides with each of the central axis D1 of substrate 110 and the optical axis D3 of the lens 131. The processor 210 and the control unit 150 may be integrated with each other as one component. The control unit 150 may have some of the functions of the processor 210, and the processor 210 may have some of the functions of the control unit 150.

The shaft 142 is provided with a rotary connection connector 170. The rotary connection connector 170 includes a ring unit 171 and a brush unit 172. The rotary connection connector 170 electrically connects the plurality of wirings 112 of the substrate 110 being rotated and the control unit 150. In the example illustrated in FIG. 2, the rotary connection connector 170 is a slip ring. However, the rotary connection connector 170 may be a rotary connector or the like using a liquid metal.

The ring unit 171 includes a tubular body 171a in which the shaft 142 is disposed and which is connected to the shaft 142, and a plurality of rings 171b each having electrical conductivity and provided on an outer periphery of the tubular body 171a. The ring unit 171 rotates together with the shaft 142. The plurality of rings 171b and the plurality of wirings 112 incorporated in the substrate 110 are electrically connected in pairs via the inside of the shaft 142 and the inside of the tubular body 171a.

The brush unit 172 includes a plurality of brushes 172a each having electrical conductivity and being in contact with the plurality of rings 171b in pairs, and a holder 172b that holds the plurality of brushes 172a. The control unit 150 is electrically connected to the motor 141 of the driving unit 140 and each brush 172a of the rotary connection connector 170.

### Operation of Light-Emitting Module According to First Embodiment

An operation of the light-emitting module 100 will be described with reference to FIGS. 6 and 7. FIG. 6 is a schematic cross-sectional view of the light-emitting module 100 illustrating an example of an emitting operation of white light by the light-emitting module 100. FIG. 7 is a schematic cross-sectional view of the light-emitting module 100 illustrating an example of an emitting operation of light when the biological photodetection information DL is output in the light-emitting module 100. The cross-sectional views of FIGS. 6 and 7 each illustrate the cross-section taken along the line II-II in FIG. 1.

In the light-emitting module 100, the control unit 150 can control the driving unit 140 to rotate the substrate 110. The rotation speed of the substrate 110 is, for example, in a range from 60 rpm (revolutions per minute) to 24000 rpm. The control unit 150 may be configured such that the control unit 150 can adjust the rotation speed of the motor 141 of the driving unit 140.

As described above, the control unit 150 of the light-emitting module 100 can switch between the emission of the white light and the emission of the light when the biological photodetection information DL is output. The control unit 150 performs the above-described switching, for example, according to an operator's input operation with respect to the light-emitting module 100.

When photographing is performed by the imaging device using the light emitted from the light-emitting module 100, the control unit 150 of the light-emitting module 100 sets a state in which the white light can be emitted as illustrated in FIG. 6. The example in FIG. 6 illustrates how emitted light L3 emitted in a spread manner from the light source 120 passes through the lens 131, is converged at the focal point F, and then is emitted onto an irradiation surface P1. The irradiation surface P1 is a virtual surface orthogonal to the rotation axis D2 and located in the +Z-direction of the lens 131.

In the state illustrated in FIG. 6, the light-emitting module 100 concurrently emits red emitted light L3 from the red light source 120r, green emitted light L3 from the green light source 120g, and blue emitted light L3 from the blue light source 120b. The emitted light L3 of each color is emitted in a corresponding one of directions different from each other from a corresponding one of positions different from each other on the substrate 110, passes through the lens 131, is converged at the focal point F, and then is emitted onto the irradiation surface P1. The red emitted light L3, the green emitted light L3, and the blue emitted light L3 are mixed, and thus mixed-color light can be obtained. The light-emitting module 100 can emit the white light composed of the mixed-color light of the emitted lights L3 of the colors onto the irradiation surface P1. A region A1 illustrated in FIG. 6 represents a region irradiated with the white light. The region A1 is a substantially circular region centered on the rotation axis D2 on the irradiation surface P1 when the irradiation surface P1 is viewed from below. The substrate 110 is rotated around the rotation axis D2 by the driving unit 140, thereby allowing the white light emitted to the region A1 to be rotated around the rotation axis D2.

When the light-emitting module 100 emits the white light, the light-receiving element 200 may be used for obtaining information related to the light amount around the light-emitting module. In the example illustrated in FIG. 6, the light-receiving element 200 of the light-emitting module 100 receives incident light L4 from the outside of the light-emitting module 100, and outputs information related to the incident light L4 to the control unit 150. The control unit 150 can adjust the light amount of the irradiation light according to the information related to the light amount of the incident light L4 input from the light-receiving element 200. For example, in an imaging device that performs photographing using the irradiation light from the light-emitting module 100 as flash light, photographing adapted to the brightness around the imaging device can be performed.

When the light-emitting module 100 outputs the biological photodetection information DL based on the light emitted from the light-emitting module 100, the control unit 150 sets a state in which the light can be emitted from at least one of the plurality of light sources 120 as illustrated in FIG. 7. The example in FIG. 7 illustrates how emitted light L5 emitted in a spread manner from at least one of the plurality of light sources 120 passes through the lens 131, is converged at the focal point F, and then is emitted onto an irradiation surface P2. The irradiation surface P2 is a virtual surface orthogonal to the rotation axis D2 and located in the +Z-direction of the lens 131, and is a surface on which a part of the biological body from which the biological information Db is obtained is located. The light-emitting module 100 can receive, via the light-receiving element 200, at least one of the reflected light and the scattered light by the biological body of the emitted light L5 emitted from the light-emitting module 100, and output the biological photodetection information DL. In the example illustrated in FIG. 7, part of at least one of the reflected light and the scattered light by the biological body is indicated by an arrow as incident light L6. For the sake of brevity, the arrow L4 in FIG. 6 and the arrow L6 in FIG. 7 are illustrated while omitting a change in a traveling direction due to a difference in refractive index between the members.

When the biological information Db is obtained, it is preferable that at least one of the reflected light and the scattered light by the biological body of the light emitted from the light-emitting module 100 is received by the light-receiving element 200 with as large a light amount as possible. Thus, the irradiation surface P2 is preferably located closer to the light-emitting module 100 than the above-described irradiation surface P1 is. The surface of the biological body may be in contact with the light-emitting surface 131b. When the surface of the biological body is in contact with the light-emitting surface 131b, the irradiation surface P2 may substantially coincide with the light-emitting surface 131b.

The light-emitting module 100 can emit at least one of red emitted light L5 from the red light source 120r, green emitted light L5 from the green light source 120g, blue emitted light L5 from the blue light source 120b, and infrared emitted light L5 from the infrared light source 120i. When the light-emitting module 100 emits two or more emitted lights L5, the light-emitting module 100 can concurrently emit these emitted lights. At least one of the emitted lights L5 of these colors and the infrared emitted light L5 is emitted from a corresponding one of positions different from each other on the substrate 110 in a corresponding one of directions different from each other, passes through the focal point F, is converged at the focal point F, and then is emitted onto the irradiation surface P2. The substrate 110 is rotated around the rotation axis D2 by the driving unit 140, and thus the light emitted onto the irradiation surface P2 is rotated around the rotation axis D2.

At least one of the lights L5 of these colors and infrared emitted light L5 emitted to the irradiation surface P2 is reflected and scattered by a part of the biological body located on the irradiation surface P2. The light-receiving element 200 can receive the incident light L6, which is at least one of the reflected light and the scattered light, and output the biological photodetection information DL.

### MODIFIED EXAMPLES

Various modified examples of the light-emitting module 100 will be described below. The same terms and reference characters as those in the previously described embodiment and modified examples indicate the same or similar members or components as those in the previously described embodiment and modified examples, and detailed explanations thereof are omitted as appropriate. This also applies to other embodiments which will be described hereinafter.

### First Modified Example

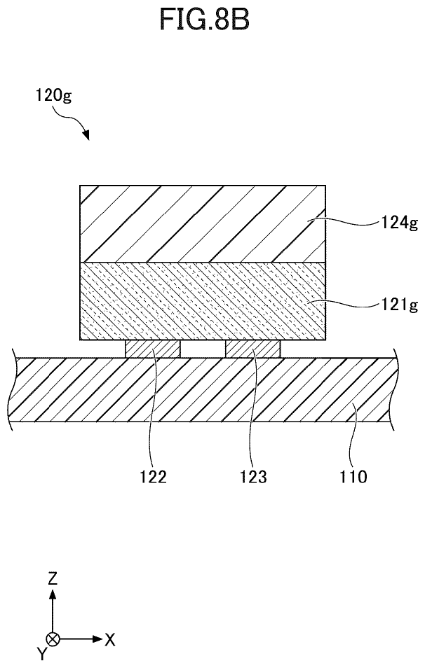

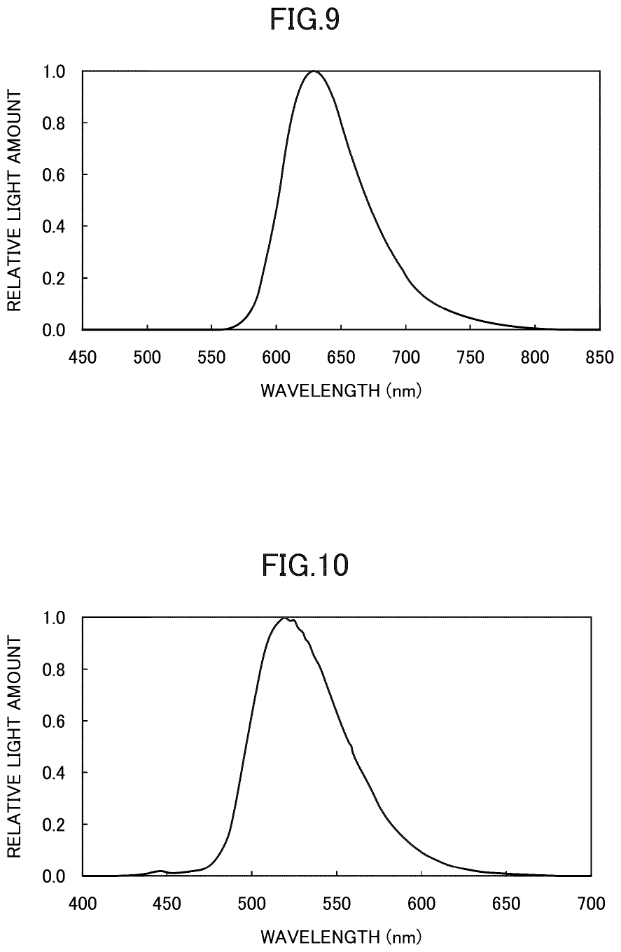

The light-emitting module 100 according to a first modified example will be described with reference to FIGS. 8A, 8B, 9, and 10. FIG. 8A is a schematic cross-sectional view illustrating an example of the configuration of the red light source 120r including a first phosphor 124r of the light-emitting module 100 according to the first modified example. FIG. 8B is a schematic cross-sectional view illustrating an example of the configuration of the green light source 120g including a second phosphor 124g of the light-emitting module 100 according to the first modified example. FIG. 9 is a diagram showing an example of an emission spectrum of the red light source including the first phosphor 124r. FIG. 10 is a diagram showing an example of an emission spectrum of the green light source including the second phosphor 124g.

In the present modified example, the red light source 120r includes a first light-emitting element 121r that emits blue light and the first phosphor 124r that converts a wavelength of at least part of the blue light emitted from the first light-emitting element 121r to emit red light. The green light source 120g includes a second light-emitting element 121g that emits blue light and the second phosphor 124g that converts a wavelength of at least part of the blue light emitted from the second light-emitting element 121g to emit green light. The above points are mainly different from the first embodiment described above.

In the example illustrated in FIG. 8A, the red light source 120r includes the first light-emitting element 121r and the first phosphor 124r disposed on an upper surface of the first light-emitting element 121r. The first phosphor 124r converts a wavelength of at least part of the light emitted from the first light-emitting element 121r. Examples of a material of the first light-emitting element 121r that can be used include a nitride semiconductor that can emit blue light. The nitride semiconductor is mainly represented by the general formula InₓAl_{y}Ga_{1-x-y}N (0≤x, 0≤y, x+y≤1). An emission peak wavelength of the first light-emitting element 121r is preferably in a range from 400 nm to 530 nm, more preferably in a range from 420 nm to 490 nm, and even more preferably in a range from 450 nm to 475 nm from the viewpoints of light emission efficiency, and color mixing relationship between the excitation of the wavelength conversion substance and the light emission of the first light-emitting element 121r, and the like. Accordingly, the first phosphor 124r can be efficiently excited. As the first phosphor, a phosphor that is excited by the blue light emitted by the first light-emitting element 121r and emits red light can be used.

In the example illustrated in FIG. 8B, the green light source 120g includes the second light-emitting element 121g and the second phosphor 124g disposed on an upper surface of the second light-emitting element 121g. The second phosphor 124g converts a wavelength of at least part of the light emitted from the second light-emitting element 121g. The same material as the material of the first light-emitting element 121r can be used as a material of the second light-emitting element 121g. A phosphor that is excited by the blue light emitted from the second light-emitting element 121g and emits green light can be used as the second phosphor.

The first phosphor 124r and the second phosphor 124g may be a light-transmissive member such as a resin containing a phosphor, or may be a sintered body of the phosphor.

Examples of the phosphor that emits visible light and can be used in the light-emitting modules of the present embodiment and the modified example include an yttrium aluminum garnet based phosphor (for example, Y₃(Al,Ga)₅O₁₂:Ce), a lutetium aluminum garnet based phosphor (for example, Lu₃(Al,Ga)₅O₁₂:Ce), a terbium aluminum garnet based phosphor (for example, Tb₃(Al,Ga)₅O₁₂:Ce), a CCA based phosphor (for example, Ca₁₀(PO₄)₆Cl₂:Eu), an SAE based phosphor (for example, Sr₄Al₁₄O₂₅:Eu), a chlorosilicate based phosphor (for example, Ca₈MgSi₄O₁₆Cl₂:Eu), an oxynitride based phosphor such as a β-SiAlON based phosphor (for example, (Si,Al)₃(O,N)₄:Eu) or an α-SiAlON based phosphor (for example, Ca(Si,Al)₁₂(O,N)₁₆:Eu), a nitride based phosphor such as an SLA based phosphor (for example, SrLiAl₃N₄:Eu), a CASN based phosphor (for example, CaAlSiN₃:Eu), or an SCASN based phosphor (for example, (Sr,Ca)AlSiN₃:Eu), a fluoride based phosphor such as a KSF based phosphor (for example, K₂SiF₆:Mn), a KSAF based phosphor (for example, K₂Si_{0.99}Al_{0.01}F_{5.99}:Mn), or an MGF based phosphor (for example, 3.5MgO·0.5MgF₂·GeO₂:Mn), a phosphor having a perovskite structure (for example, CsPb(F,Cl,Br,I)₃), and a quantum dot phosphor (for example, CdSe, InP, AgInS₂, or AgInSe₂). The KSAF based phosphor may have a composition represented by Formula (I).

M₂[SiₚAl_{q}MnᵣFₛ] (I)

In Formula (I), M represents an alkali metal and may include at least K. Mn may be a tetravalent Mn ion. p, q, r, and s may satisfy 0.9≤p+q+r≤1.1, 0<q≤0.1, 0<r≤0.2, and 5.9≤s≤6.1. Preferably, 0.95≤p+q+r≤1.05 or 0.97≤p+q+r≤1.03, 0<q≤0.03, 0.002≤q≤0.02 or 0.003≤q≤0.015, 0.005≤r≤0.15, 0.01≤r≤0.12 or 0.015≤r≤0.1, 5.92≤s≤6.05 or 5.95≤s≤6.025. Examples of the composition represented by Formula (I) include compositions represented by K₂ [Si_{0.946}Al_{0.005}Mn_{0.049}F_{5.995}], K₂ [Si_{0.942}Al_{0.008}Mn_{0.050}F_{5.992}], K₂ [Si_{0.939}Al_{0.014}Mn_{0.047}F_{5.986}]. Such a KSAF based phosphor enables red light emission having a high luminance and a narrow half-value width of the light emission peak wavelength.

A semiconductor element that emits red light is used as the red light source and a semiconductor element that emits green light is used as the green light source. In such a case, as described above with reference to FIGS. 3 and 4 for example, the wavelength region of light emitted from each of the red light source and the green light source is narrow, and thus a wavelength region with a small light amount occurs in an orange wavelength region or the like between red and green wavelength regions, and reflected light accurately reflecting the color of an object may not be obtained. When the reflected light accurately reflecting the color of the object is not obtained, the color of the object cannot be accurately represented in the image shot using the light emitted from the light-emitting module.

In the present modified example, as shown in FIG. 9, the emission spectrum of the red light source 120r has a wider wavelength region than the red light relative light amount distribution 31 shown in FIG. 3 of the emission by the red light source 120r included in the light-emitting module 100 according to the first embodiment. As shown in FIG. 10, the emission spectrum of the green light source 120g has a wider wavelength region than the green light relative light amount distribution 32 shown in FIG. 3 of the emission by the green light source 120g included in the light-emitting module 100 according to the first embodiment. Accordingly, the light-emitting module 100 according to the first modified example can suppress the lack in the light amount in the boundary wavelength region 34 between the red light relative light amount distribution 31 and the green light relative light amount distribution 32 as shown in FIG. 3, and can obtain the reflected light accurately reflecting the color of the object. As a result, in the present modified example, the color of the object can be accurately expressed in the image shot using the irradiation light from the light-emitting module 100.

### Second Modified Example

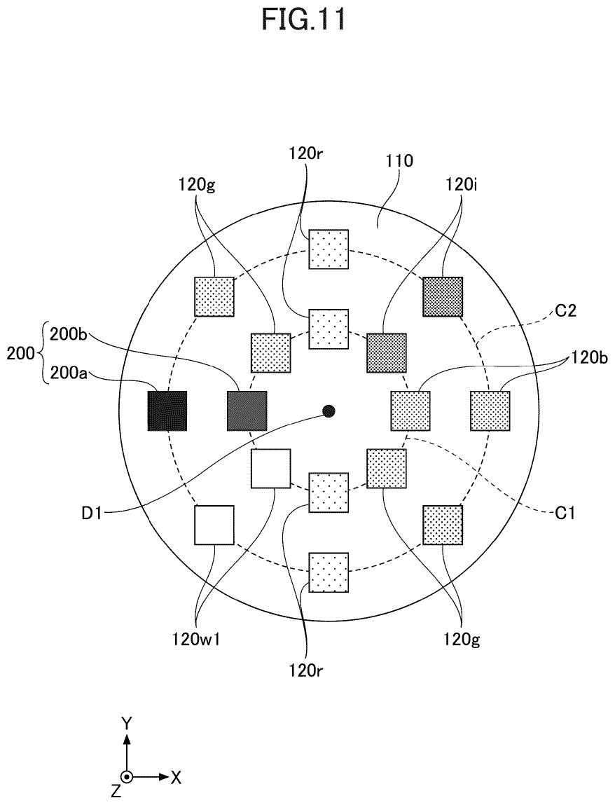

Next, a light-emitting module according to a second modified example will be described with reference to FIG. 11. FIG. 11 is a schematic top view illustrating the substrate 110 on which the light sources 120 are disposed in the light-emitting module according to the second modified example.

In the present modified example, at least one light-receiving element 200 includes a plurality of light-receiving portions each having different spectral responsivity. The second modified example is mainly different from the first embodiment in that the plurality of light-receiving portions can further output photodetection information related to ambient light (that is, light around the light-emitting module).

In the example illustrated in FIG. 11, the light-receiving element 200 includes a first light-receiving portion 200a and a second light-receiving portion 200b as the plurality of light-emitting portions. The spectral responsivity of the first light-receiving portion 200a is different from the spectral responsivity of the second light-receiving portion 200b. Each of the first light-receiving portion 200a and the second light-receiving portion 200b outputs, via the control unit 150 illustrated in FIG. 2, the photodetection information related to the ambient light to an external device such as an imaging device that performs photographing using the light emitted from the light-emitting module. The external device can obtain the information related to the ambient light based on the photodetection information received from each of the first light-receiving portion 200a and the second light-receiving portion 200b. The information related to the ambient light received by the light-receiving element 200 may be obtained by the control unit 150 and passed from the control unit 150 to the external device.

The substrate 110 illustrated in FIG. 11 includes a first virtual circle C1 located on the inner side and a second virtual circle C2 located on the outer side in a top view. Each of the first virtual circle C1 and the second virtual circle C2 is a virtual circle centered on the central axis D1. On the first virtual circle C1, two red light sources 120r located across the central axis D1, two green light sources 120g located across the central axis D1, one blue light source 120b, one infrared light source 120i, one white light source 120w1, and the second light-receiving portion 200b are disposed. On the second virtual circle C2, two red light sources 120r located across the central axis D1, two green light sources 120g located across the central axis D1, one blue light source 120b, one infrared light source 120i, one white light source 120w1, and the first light-receiving portion 200a are disposed.

For example, when photographing is performed by the imaging device using the light emitted from the light-emitting module, the imaging device preferably varies white balance, color temperature of the light emitted from the light-emitting module, or the like according to whether a place where the imaging device is located at the time of photographing is indoors or outdoors. By controlling the white balance, the color temperature of the irradiation light, or the like according to whether the place where the imaging device is located at the time of photographing is indoors or outdoors, the imaging device can perform the photographing accurately expressing the color of an object.

The imaging device using the irradiation light from the light-emitting module according to the present modified example obtains ratio information of the infrared light included in the ambient light based on ambient light photodetection information received from the first light-receiving portion 200a and the second light-receiving portion 200b. Because the ratio of the infrared light included in the ambient light is different between indoors and outdoors, the imaging device can determine whether the place where the light-emitting module and the imaging device are located at the time of photographing is outdoors or indoors based on the ratio information of the infrared light included in the ambient light. Specifically, when the ratio of the infrared light included in the ambient light is equal to or greater than a predetermined threshold value, the imaging device determines that the place where the light-emitting module and the imaging device are located at the time of photographing is outdoors. On the other hand, when the ratio of the infrared light included in the ambient light is not equal to or greater than the predetermined threshold value, the imaging device determines that the place where the light-emitting module and the imaging device are located at the time of photographing is indoors. By controlling the white balance, the color temperature of the irradiation light, or the like according to the determination result, the imaging device can perform the photographing accurately expressing the color of the object.

The ambient light photodetection information is not limited to the ratio information of the infrared light included in the ambient light, and may be information related to light amounts of various wavelengths, information related to light amount distributions of a plurality of wavelengths, or the like. Further, the control by the external device that has received the ambient light photodetection information is not limited to the control according to whether the place where the light-emitting module and the external device are located at the time of photographing is indoors or outdoors. For example, the external device that has received the ambient light photodetection information can determine whether the lighting device that illuminates the surroundings of the light-emitting module and the external device is an incandescent lamp, a fluorescent lamp, an LED lighting, or the like, and control the color temperature or the like of the irradiation light.

The spectral responsivities of the plurality of light-receiving portions may be made different by making materials or the like constituting the light-receiving portions different from each other, or may be made different by disposing optical elements having spectral characteristics different from each other on the light-receiving portions, respectively.

In the light-emitting module according to the present modified example, when the biological information Db is obtained, the biological photodetection information DL output from at least one of the first light-receiving portion 200a and the second light-receiving portion 200b can be used.

### Third Modified Example

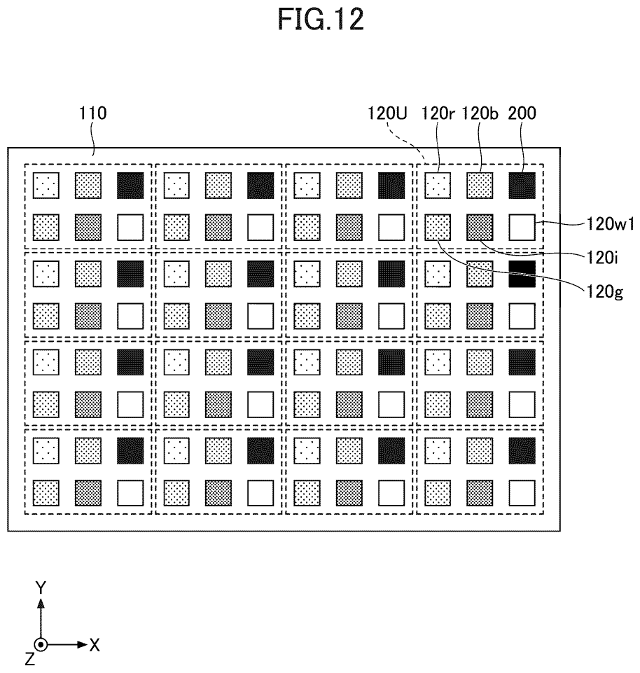

Next, a light-emitting module according to a third modified example will be described with reference to FIG. 12. FIG. 12 is a schematic top view illustrating the substrate 110 on which a plurality of light sources are disposed in the light-emitting module according to the third modified example.

In the present modified example, the plurality of light sources include a plurality of light source units 120U arranged side by side on lattice points in the X-direction and the Y-direction on the substrate 110. Each of the plurality of light source units 120U includes a red light source 120r, a green light source 120g, a blue light source 120b, an infrared light source 120i, a white light source 120w1, and a light-receiving element 200. The present modified example is different from the first embodiment mainly in that the red light sources 120r, the green light sources 120g, the blue light sources 120b, the infrared light sources 120i, the white light sources 120w1, and the light-receiving elements 200 are arranged on the lattice points side by side in the X-direction and the Y-direction on the substrate 110.

Also in the present modified example, it is possible to provide the light-emitting module that can emit the white light and can output the biological photodetection information used for obtaining the biological information. The plurality of light sources may include at least one light source unit 120U. The plurality of light source units 120U does not have to be arranged side by side on the lattice points in the X-direction and the Y-direction, and may be arranged at any positions in the X-direction and the Y-direction. The light source unit 120U is not limited to a configuration in which one red light source 120r, one green light source 120g, one blue light source 120b, one infrared light source 120i, one white light source 120w1, and one light-receiving element 200 are provided. The quantity of each of the light sources and the quantity of the light-receiving elements may each be two or more, or at least one of the quantity of each of the light sources of these colors and infrared light source and the quantity of the light-receiving elements may be different.

### Second Embodiment

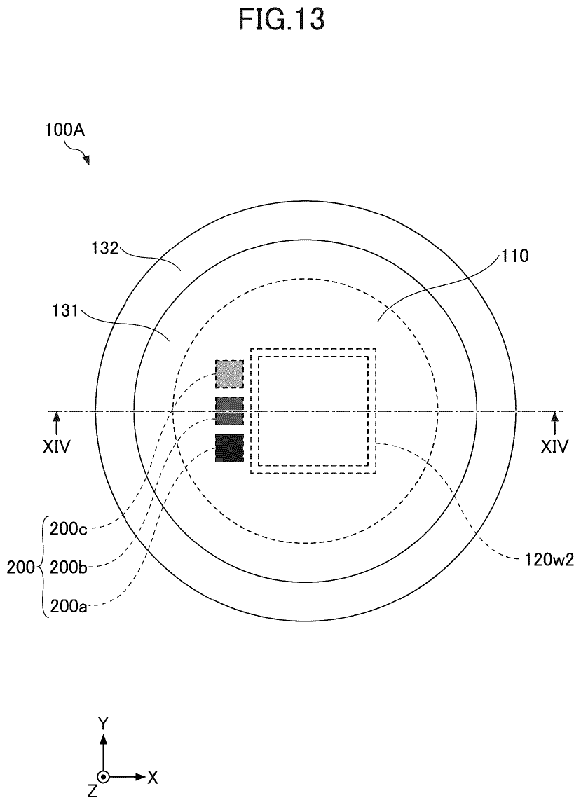

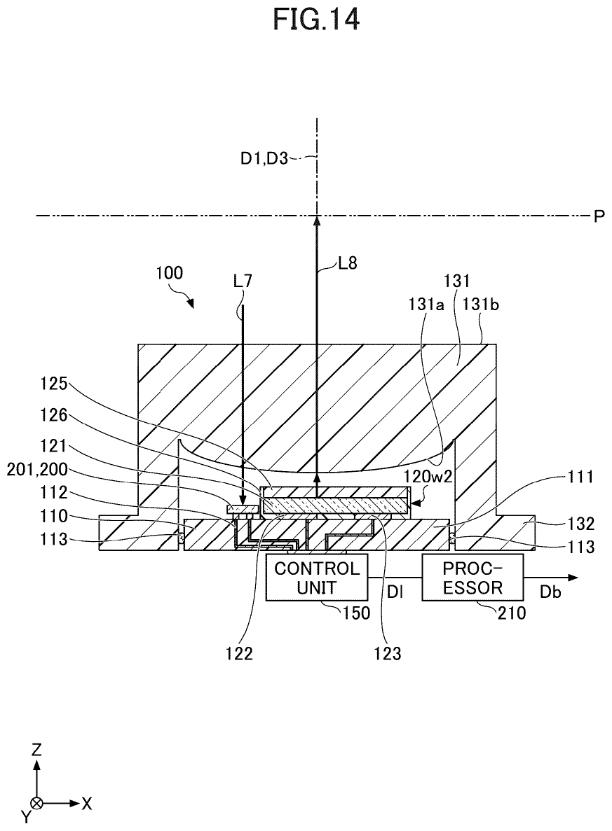

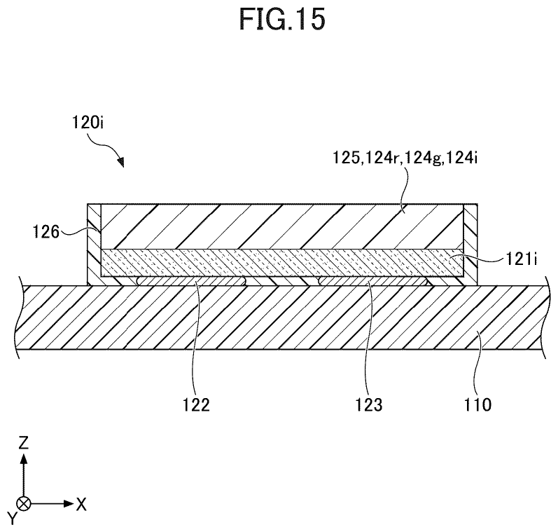

Next, a light-emitting module according to a second embodiment will be described with reference to FIGS. 13 to 15. FIG. 13 is a schematic top view illustrating a light-emitting module 100A according to the second embodiment. FIG. 14 is a schematic cross-sectional view illustrating an example taken along line XIV-XIV in FIG. 13. FIG. 15 is a schematic cross-sectional view illustrating an example of the configuration of the infrared light source 120i including a third phosphor 124i of the light-emitting module 100A. In FIG. 14, part of light emitted from a white light source 120w2 included in the light-emitting module 100A is indicated by an arrow as emitted light L8, and part of light entering into the light-emitting module 100A from the outside of the light-emitting module 100A is indicated by an arrow as entering light L7. In the entering light L7 and the emitted light L8 in FIG. 14, a change in a traveling direction due to a difference in refractive index between the members is omitted.

In the present embodiment, at least one light source 120 is the white light source 120w2 that emits white light. The white light source 120w2 includes a light-emitting element 121 that emits blue light and a wavelength conversion member 125 disposed on the light-emitting element 121. The wavelength conversion member 125 includes a first phosphor 124r that converts a wavelength of at least part of the blue light emitted from the light-emitting element 121 to emit red light, a second phosphor 124g that converts a wavelength of at least part of the blue light emitted from the light-emitting element 121 to emit green light, and a third phosphor 124i that converts a wavelength of at least part of the blue light emitted from the light-emitting element 121 to emit infrared light.

In the present embodiment, the at least one light-receiving element 200 includes a first light-receiving portion 200a, a second light-receiving portion 200b, and a third light-receiving portion 200c each having different spectral responsivity. The first light-receiving portion 200a has light reception sensitivity in a red region. The second light-receiving portion 200b has light reception sensitivity in a green region. The third light-receiving portion 200c has light reception sensitivity in an infrared region. The first light-receiving portion 200a, the second light-receiving portion 200b, and the third light-receiving portion 200c are examples of the plurality of light-receiving portions each having different spectral responsivity. The above points are mainly different from the first embodiment.

In the example illustrated in FIG. 13, one white light source 120w2 is disposed on the substrate 110. In the example illustrated in FIG. 14, the white light source 120w2 includes the light-emitting element 121, the wavelength conversion member 125 disposed on the light-emitting element 121, and a light-shielding member 126 that covers lateral surfaces of the light-emitting element 121 and the wavelength conversion member 125.

The light-emitting module 100A can irradiate the irradiation surface P with red, green, blue, and infrared light components included in the white light emitted from the white light source 120w2. The emitted light L8 may pass through the lens 131, be converged at the focal point F, and then be emitted onto the irradiation surface P.

When photographing is performed by the imaging device using the light emitted from the light-emitting module 100, the light-emitting module 100A can emit the white light emitted from the white light source 120w2. On the other hand, when the light-emitting module 100A outputs the biological photodetection information DL, the light-emitting module 100A can output the biological photodetection information obtained by allowing each of the first light-receiving portion 200a, the second light-receiving portion 200b, and the third light-receiving portion 200c to receive at least one of the reflected light and the scattered light of the emitted light L from the white light source 120w2 by the biological body.

As described above, the light-emitting module 100A can emit the white light composed of the emitted light L8. The processor 210 or the external device that receives the biological photodetection information DL output from the light-emitting module 100 can obtain the biological information Db related to the biological body based on the biological photodetection information DL. As described above, in the present embodiment, it is possible to provide the light-emitting module 100A that can emit the white light and can output the biological photodetection information DL used for obtaining the biological information Db.

Further, in the present embodiment, the light-emitting module 100A includes the white light source 120w2, and thus the light-emitting module 100A can output the biological photodetection information DL obtained by receiving at least one of the reflected light and the scattered light by the biological body of concurrently emitted lights of these colors and infrared light. Accordingly, the light-emitting module 100A does not need to sequentially emit the light of each color and infrared light, and thus the light-emitting module 100A can efficiently output the biological photodetection information DL.

In the light-emitting module 100A illustrated in FIG. 13, at least one light-receiving element 200 includes the plurality of light-receiving portions each having different spectral responsivity. The plurality of light-receiving portions include the first light-receiving portion 200a, the second light-receiving portion 200b, and the third light-receiving portion 200c. In the example illustrated in FIG. 13, a set of the first light-receiving portion 200a, the second light-receiving portion 200b, and the third light-receiving portion 200c arranged in the Y-direction is disposed on the −X side of one white light source 120w2.

Each of the first light-receiving portion 200a, the second light-receiving portion 200b, and the third light-receiving portion 200c outputs the biological photodetection information DL to the processor 210 via the control unit 150. The processor 210 receives information related to light for each wavelength in the light received by the light-receiving element 200, as the biological photodetection information DL. The light-receiving element 200 receives that information from the first light-receiving portion 200a, the second light-receiving portion 200b, and the third light-receiving portion 200c. The processor 210 can obtain the biological information Db by calculation based on the received biological photodetection information DL. For example, the processor 210 can obtain pulse information from the biological photodetection information DL related to at least green light, and can obtain blood oxygen concentration information from the biological photodetection information DL related to red light and infrared light.

As described above, in the light-emitting module 100A, the processor 210 can obtain the biological information Db based on the biological photodetection information DL obtained by receiving at least one of the reflected light and the scattered light by the biological body of the emitted light of each color and infrared light. Accordingly, the light-emitting module 100A does not need to sequentially emit the light of each color and infrared light, and thus the light-emitting module 100A can efficiently obtain the biological information Db. From the viewpoint of increasing the acquisition accuracy of the biological information Db, it is preferable that the white light source 120w2 emit white light having a small difference in light amount between wavelengths.

### White Light Source 120w2

As illustrated in FIG. 15, the wavelength conversion member 125 includes a first phosphor 124r that converts a wavelength of at least part of the light emitted from the light-emitting element 121 to emit red light, a second phosphor 124g that converts a wavelength of at least part of the blue light emitted from the light-emitting element 121 to emit green light, and a third phosphor 124i that converts a wavelength of at least part of the light emitted from the light-emitting element 121 to emit infrared light.

Among the above-described phosphors, a phosphor that is excited by blue light emitted by the light-emitting element 121 and emits red light can be used as the first phosphor 124r. Among the above-described phosphors, a phosphor that is excited by the blue light emitted by the light-emitting element 121 and emits green light can be used as the second phosphor 124g. A phosphor that is excited by blue light emitted from the light-emitting element 121 and emits infrared light can be used as the third phosphor 124i.

As the phosphor that emits infrared light, it is preferable to use an infrared phosphor having an emission peak wavelength in a wavelength range from 800 nm to 1000 nm in consideration of a difference in light absorption rate between oxygenated hemoglobin and reduced hemoglobin and light reception sensitivity of the light-receiving element. Examples of the infrared phosphor include a phosphor having a composition included in the compositional formula represented by Formula (1) as an oxide phosphor below.

$${( {Mg}_{1 - t} {M}_{t}^{1} )}_{u} {( {Ga}_{1 - v - x - y} {M}_{v}^{2} )}_{2} {O}_{w} : {Cr}_{x} , {M}_{y}^{3} \qquad ( II )$$

In Formula (1), t, u, v, w, x, and y satisfy 0≤t≤0.8, 0.7≤u≤1.3, 0≤v≤0.8, 3.7≤w≤4.3, 0.02≤x≤0.3, 0≤y≤0.2, and y<x.

In the oxide phosphor, the first element M¹ preferably includes at least one element selected from the group consisting of Ca, Sr, Ni, and Zn, the second element M² preferably includes at least one element selected from the group consisting of Al and Sc, and the third element M³ preferably includes at least one element selected from the group consisting of Eu, Ce, Ni, and Mn.

These are examples of phosphors that emit infrared light, and known infrared phosphors other than the phosphors described above can be used.

The light-shielding member 126 includes, for example, a light-transmissive base material such as a resin and a light-diffusing material, and diffuses and reflects light emitted from the light-emitting element 121 and the wavelength conversion member 125 via the light-diffusing material. Accordingly, emission of light that does not propagate through the wavelength conversion member 125 from the lateral surface of the light-emitting element 121 can be suppressed. As a result, luminance unevenness of the light emitted from the white light source 120w2 can be suppressed. Examples of the resin material included in the light-shielding member 126 that can be used include a silicone resin, an epoxy resin, phenol resin, a polycarbonate resin, or an acrylic resin, and modified resins thereof. Examples of the light-diffusing material included in the light-shielding member 126 that can be used include titanium oxide and magnesium oxide.

### Third Embodiment

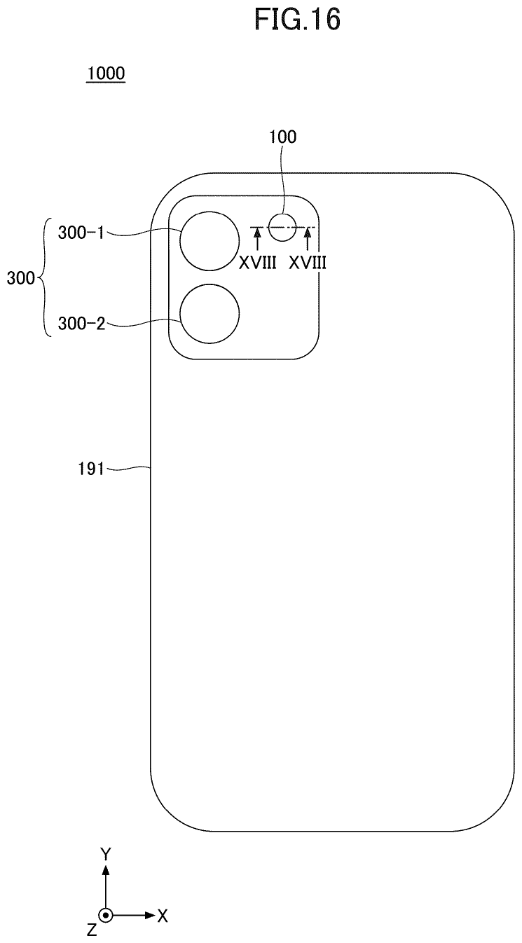

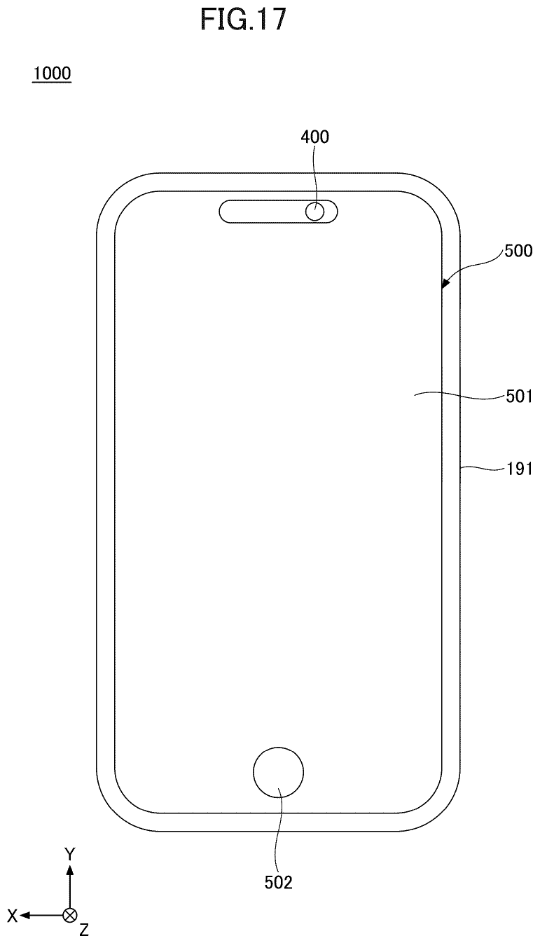

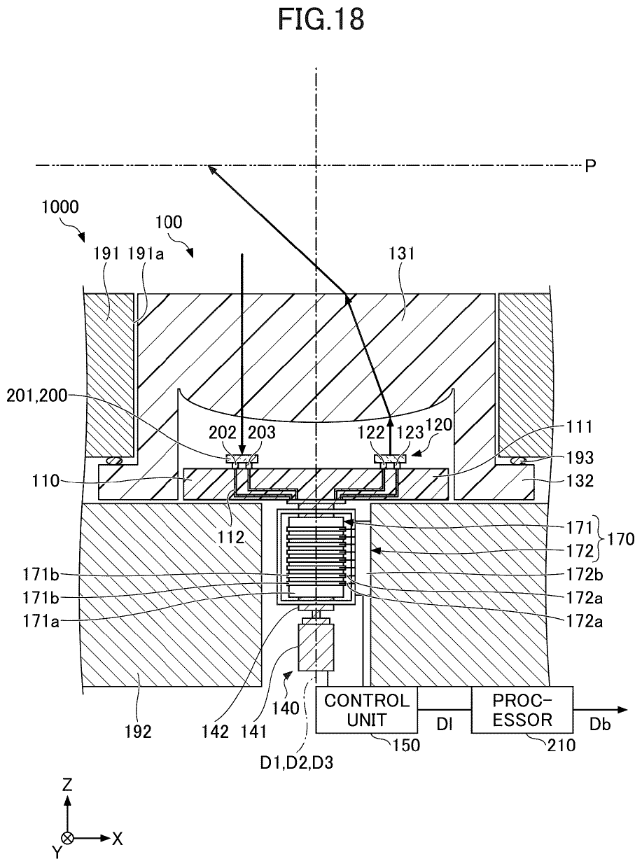

Next, a smartphone according to a third embodiment will be described with reference to FIGS. 16 to 18. FIG. 16 is a schematic view of a smartphone 1000 according to the third embodiment viewed from the side opposite to a display surface 501 side. FIG. 17 is a schematic view of the smartphone 1000 viewed from the display surface 501 side. FIG. 18 is a schematic cross-sectional view taken along line XVIII-XVIII illustrated in FIG. 16. The display surface 501 side corresponds to the −Z side.

In the example illustrated in FIGS. 16 and 17, the smartphone 1000 includes a light-emitting module 100, an imaging device 300, a housing 191, a front camera 400, and a display unit 500 including the display surface 501. The imaging device 300 includes an imaging device 300-1 and an imaging device 300-2. The light-emitting module 100 and the imaging device 300 are disposed so as to be partially exposed on the +Z side from the housing 191 of the smartphone 1000. The front camera 400 and the display unit 500 are disposed so as to be partially exposed on the −Z side from the housing 191 of the smartphone 1000.

The light emitted from the light-emitting module 100 is used to irradiate a subject with light in photographing by using the imaging device 300-1 and the imaging device 300-2. The smartphone 1000 may include at least one of the light-emitting module 100 and the light-emitting module 100A.

The light emitted from the light-emitting module is used to output the biological photodetection information obtained by receiving at least one of the reflected light and the scattered light by a biological body. Specifically, a part of the biological body (for example, a peripheral part such as a human finger) is brought into contact with the irradiation surface of the light-emitting module 100 exposed from the housing 191 of the smartphone 1000 to emit light, and at least one of the reflected light and the scattered light by the biological body is received; thus, the biological photodetection information can be output.

The smartphone 1000 includes the light-emitting module 100, and thus the smartphone 1000 can emit white light and can obtain the biological information Db based on the biological photodetection information DL output from the light-emitting module 100.

Examples of the imaging device 300 include a camera for photographing a still image and a video camera for photographing a moving image. Specifications of the imaging device 300-1 and the imaging device 300-2 may be the same or different from each other. For example, the imaging device 300-1 and the imaging device 300-2 may be different from each other in specifications such as photographing resolution or a photographing angle of view. The imaging device 300 may include three or more imaging devices, or may include two or less imaging devices. The arrangement of the imaging device 300 and the light-emitting module 100 can also be changed as appropriate according to specifications required for the smartphone 1000.

The housing 191 is a box-shaped member that houses the light-emitting module 100, the imaging device 300, the front camera 400, the display unit 500, a control substrate for these components, and the like. Examples of a material of the housing 191 that can be used include a resin material and a metal material. The size, shape, or the like of the housing 191 can be changed as appropriate according to specifications required for the smartphone 1000.

The front camera 400 is an imaging device by which the operator of the smartphone photographs himself/herself or a plurality of persons including himself/herself. The front camera 400 can also be referred to as a selfie imaging device. The front camera 400 is used for a videophone using the smartphone 1000, photographing of a moving image, personal authentication, and the like.

The display unit 500 displays various images such as an operation image for operating the smartphone 1000, an image displayed by execution of an application program, and an image shot by the imaging device 300 on the display surface 501. The application program is a program installed in the smartphone, an external server communicably connected to the smartphone, or the like. The display unit 500 includes an organic electroluminescence (EL) panel or a liquid crystal panel, or the like. The display unit 500 of the smartphone 1000 has a touch panel function on the display surface 501. A photographing button 502 in FIG. 17 is a user interface (UI) displayed on the display surface 501. At least one of the imaging device 300 and the front camera 400 can perform photographing according to a touch operation of the photographing button 502 by the operator of the smartphone 1000.

In the example illustrated in FIG. 18, an opening 191a is provided in the housing 191 of the smartphone 1000. The lens 131 is disposed in the opening 191a. The support portion 132 is fixed to a component 192 of the smartphone 1000 disposed in the housing 191 of the smartphone 1000. Between the support portion 132 and the housing 191, a close contact member 193 that is in close contact with the support portion 132 and the housing 191 is provided. Examples of the close contact member 193 that can be used include elastic materials such as natural rubber and synthetic rubber. The shape of the close contact member 193 in a top view is a ring shape. The close contact member 193 can suppress entry of a dust and a liquid through a gap between the lens 131 and the housing 191. However, a position of the close contact member 193 is not limited to the above-described position as long as the entry of the dust or the liquid from the gap between the lens 131 and the housing 191 can be suppressed. For example, the close contact member 193 can be provided in a gap between the housing 191 and a portion of the lens 131 other than the support portion 132. The lens 131 does not have to be provided with the support portion 132, and the lens 131 itself may be fixed to the housing 191.

The control unit 150 and the brush unit 172 are fixed to the component 192 of the smartphone 1000. Thus, when the motor 141 is driven, the control unit 150 and the brush unit 172 can transmit an electrical signal to the ring unit 171 without rotating.

While preferred embodiments have been described in detail above, the disclosure is not limited to the above-described embodiments, various modifications and substitutions can be made to the above-described embodiments without departing from the scope described in the claims.

The ordinal numbers, quantity, and the like used in the description of the embodiments all are exemplified to specifically describe the technology of the present disclosure, and the present disclosure is not limited to the numbers exemplified. In addition, the connection relationship between the components is exemplified for specifically describing the technique of the present disclosure, and the connection relationship for realizing the function of the present disclosure is not limited thereto.

The light-emitting module and the smartphone according to the present disclosure can emit the white light and can output the biological photodetection information used for obtaining biological information. Thus, the light-emitting module and the smartphone can be suitably used for lighting, the flash of the camera, vital check of the biological body, and the like. However, the light-emitting module and the smartphone of the present disclosure are not limited to these uses. The device including the light-emitting module of the present disclosure is not limited to the smartphone, and can be suitably used for mobile devices such as a smartwatch, a laptop PC, and a tablet terminal.

What is claimed is:

1. A light-emitting module comprising:
a substrate;
a plurality of light sources disposed on the substrate, the plurality of light sources comprising a red light source, a green light source, a blue light source, and an infrared light source;
at least one light-receiving element disposed on the substrate; and
a lens disposed facing the plurality of light sources and the at least one light-receiving element; wherein:
the red light source comprises:
a first light-emitting element configured to emit blue light, and
a first phosphor configured to convert a wavelength of at least part of the blue light emitted from the first light-emitting element to emit red light; and
the at least one light-receiving element is configured to output biological photodetection information obtained by receiving light that has been reflected and/or scattered by a biological body after being emitted from at least one of the plurality of light sources.

2. The light-emitting module according to claim 1, wherein:
the green light source comprises:
a second light-emitting element configured to emit blue light, and
a second phosphor configured to convert a wavelength of at least part of the blue light emitted from the second light-emitting element to emit green light.

3. The light-emitting module according to claim 2, wherein the plurality of light sources further comprise a white light source.

4. The light-emitting module according to claim 1, further comprising a processor configured to output biological information related to the biological body on the basis of the biological photodetection information output from the light-receiving element.

5. The light-emitting module according to claim 1, wherein the plurality of light sources are arranged in a circular ring shape.

6. The light-emitting module according to claim 1, further comprising a driving unit configured to rotate the substrate around a central axis of the circular ring shape as a rotation axis.

7. The light-emitting module according to claim 6, wherein the rotation axis of the substrate coincides with an optical axis of the lens.

8. The light-emitting module according to claim 1, further comprising a control unit configured to control emission of the light from the plurality of light sources.

9. The light-emitting module according to claim 1, wherein:
the at least one light-receiving element comprises a plurality of light-receiving portions each having different spectral responsivity; and
the plurality of light-receiving portions are configured to further output photodetection information related to ambient light.

10. A smart phone comprising:
the light-emitting module according to claim 1.

11. A light-emitting module comprising:
a substrate;
at least one light source disposed on the substrate;
at least one light-receiving element disposed on the substrate; and
a lens disposed facing the at least one light source and the at least one light-receiving element; wherein:
the at least one light source is a white light source configured to emit white light;
the white light source comprises:
a light-emitting element configured to emit blue light, and
a wavelength conversion member disposed on the light-emitting element; and
the wavelength conversion member comprises:
a first phosphor configured to convert a wavelength of at least part of the blue light emitted from the light-emitting element to emit red light,
a second phosphor configured to convert a wavelength of at least part of the blue light emitted from the light-emitting element to emit green light, and
a third phosphor configured to convert a wavelength of at least part of the blue light emitted from the light-emitting element to emit infrared light.

12. The light-emitting module according to claim 11, wherein the at least one light-receiving element comprises a plurality of light-receiving portions each having different spectral responsivity.

13. A smartphone comprising:
a flash light source comprising the light-emitting module according to claim 11.
